(19) United States
(12) Patent Application Publication
(10) Pub. No.: US 2025/0366100 A1
(43) Pub. Date: Nov. 27, 2025

(54) SEMICONDUCTOR DEVICES AND METHODS OF MANUFACTURING THEREOF

(71) Applicant: Taiwan Semiconductor Manufacturing Company, Ltd., Hsinchu (TW)

(72) Inventors: Chia-Chung Chen, Keelung (TW); Zi-Ang Su, Longtan Township (TW); Ya Yun Liu, Jhubei City (TW); Yi-Kan Cheng, Taipei (TW)

(73) Assignee: Taiwan Semiconductor Manufacturing Company, Ltd., Hsinchu (TW)

(21) Appl. No.: 19/293,849

(22) Filed: Aug. 7, 2025

Related U.S. Application Data
(62) Division of application No. 17/850,750, filed on Jun. 27, 2022.
(60) Provisional application No. 63/316,692, filed on Mar. 4, 2022.

(51) Int. Cl. H10D 62/10; H10D 30/01; H10D 30/43; H10D 30/67; H10D 84/01; H10D 84/03

(52) U.S. Cl. CPC H10D 62/121; H10D 30/014; H10D 30/43; H10D 30/6735; H10D 30/6757; H10D 84/0128; H10D 84/038

(57) ABSTRACT

A method for fabricating semiconductor devices is disclosed herein. The method includes forming a first gate region extending into a substrate and having at least a vertical portion of a first U-shape, where the first gate region has a first conductive type. The method includes forming a channel region extending into the substrate and having a second U-shape surrounded by the first U-shape, where the channel region has a second conductive type. The method includes forming a pair of first epitaxial structures coupled to end portions of the first gate region, respectively, where the first epitaxial structures have the first conductive type. The method includes forming a pair of second epitaxial structures coupled to end portions of the channel region, respectively, where the second epitaxial structures have the second conductive type. The method includes forming a third epitaxial structure having the first conductive type and surrounded by the second U-shape.

### CROSS-REFERENCE TO RELATED APPLICATION

This application is a divisional of U.S. patent application Ser. No. 17/850,750, filed Jun. 27, 2022, which claims priority to and the benefit of U.S. Provisional Application No. 63/316,692, filed Mar. 4, 2022, the disclosures of both of which are incorporated herein by reference in their entireties for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more different and/or identical components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example flow chart of a method for fabricating a semiconductor device, in accordance with some embodiments.

FIGS. 2, 3, 4, 5, 6, 7, 8, 9, 10, and 11 illustrate cross-sectional views of an example semiconductor device during various fabrication stages, made by the method of FIG. 1, in accordance with some embodiments.

FIG. 12 is an example layout for fabricating at least a portion of the semiconductor device, made by the method of FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In contemporary semiconductor device fabrication processes, a large number of semiconductor devices, such as field-effect-transistors are fabricated on a single wafer. Metal-Oxide-Semiconductor-based (MOS-based) field-effect-transistors are widely used. Such a MOS-based field-effect-transistor typically makes use of the interface between a semiconductor body and an overlying dielectric (e.g., oxide) layer to create a channel region within the semiconductor body controlled by a (e.g., metal) gate structure placed on top of the dielectric layer. In general, the surface of the semiconducting body may be inverted by the application of a voltage across the dielectric layer. The inverted surface forms a well that is bounded by the non-inverted semiconductor body and the dielectric layer. This surface region typically has excellent carrier confinement, high speed, good carrier mobility and velocity, and good on-to-off current ratios. Because such MOS-based transistors have the channel at the semiconductor body-dielectric interface, they are generally sensitive to the properties of the interface.

Various MOS-based transistor architectures have been proposed and adopted by the industry. For example, non-planar transistor architectures, such as fin-based transistors (typically referred to as FinFETs), can provide increased device density and increased performance over planar transistor architectures. Further, some advanced non-planar transistor device architectures, such as nanosheet, nanowire, or otherwise nanostructure transistors (sometimes referred to as gate-all-around (GAA) transistors), can further increase the performance over the FinFETs. When compared to the FinFET where the channel is partially wrapped (e.g., straddled) by a gate structure, the nanosheet transistor, in general, includes a gate structure that wraps around the full perimeter of one or more nanosheets for improved control of channel current flow.

As the gate length and the dielectric thickness is reduced to obtain high speeds (e.g., due primarily to less transit time for carrier movement), an interface quality of the dielectric layer becomes increasingly important in determining overall performance of the transistor. In general, a poor interface quality (e.g., a substantial number of dielectric traps) can induce an increased amount of flicker noise, which makes the MOS-based transistors an undesired candidate for applications in analog and/or RF circuits. In this regard, junction field-effect-transistor (JFET) architectures have been proposed to provide various useful characteristics, such as low noise, fast switching speed, high power handling capability, etc.

The present disclosure provides various embodiments of a semiconductor device including at least one junction field-effect-transistor (JFET) and at least one gate-all-around field-effect-transistor (GAA FET) integrated with each other, which allows the semiconductor device, as disclosed herein, to provide both low flicker noise and high speed performance. By adopting an architecture with a lower gate and an upper gate, at least some of the respective features of the GAA FET and JFET (e.g., their respective source/drain structures and the upper gate) can be concurrently formed. As such, corresponding cost to fabricate the disclosed semiconductor device can be significantly reduced. Further, by further extending the upper gate into a substrate (e.g., through forming a well region), a channel formed in the JFET can be further pushed away from a top surface of the substrate. For example, such a channel can be “buried” in the substrate and, thus, not in direct contact with one or more dielectric isolation regions which may sometimes induce dielectric traps at its interface between a semiconductor body (e.g., substrate). Consequently, the JFET integrated in the disclosed semiconductor device can significantly lower an amount of its flicker noise.

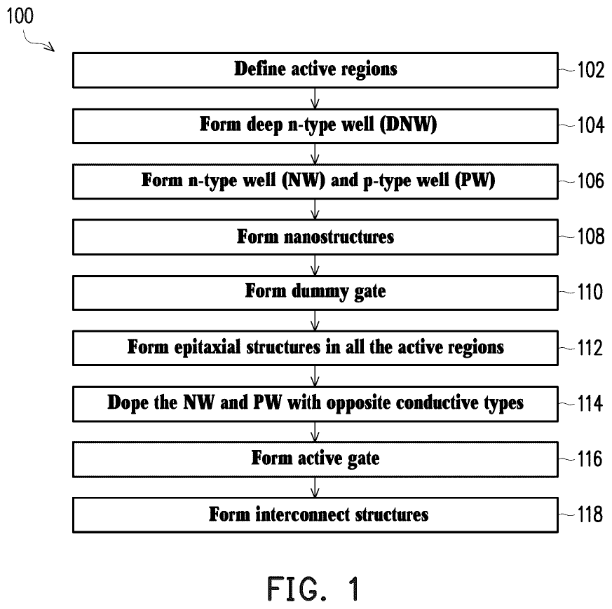

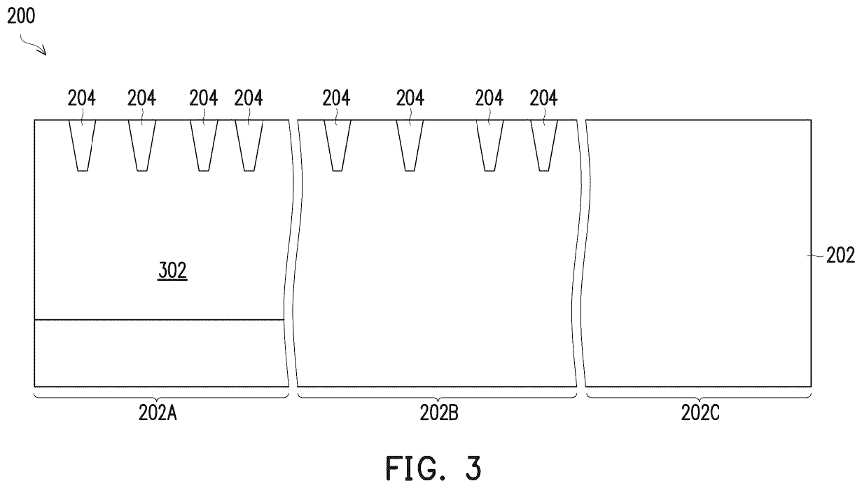

FIG. 1 illustrates a flowchart of a method 100 to form a semiconductor device, according to one or more embodiments of the present disclosure. For example, at least some of the operations (or steps) of the method 100 can be performed to fabricate, make, or otherwise form a semiconductor device including at least one JFET and one GAA FET. It is noted that the method 100 is merely an example, and is not intended to limit the present disclosure. Accordingly, it should be understood that additional operations may be provided before, during, and after the method 100 of FIG. 1, and that some other operations may only be briefly described herein. In some embodiments, operations of the method 100 may be associated with cross-sectional views of an example semiconductor device 200 at various fabrication stages as shown in FIGS. 3, 4, 5, 6, 7, 8, 9, and 10, respectively, which will be discussed in further detail below.

In brief overview, the method 100 starts with operation 102 of defining a first active region, a second active region, and a third active region over a substrate. The method 100 continues to operation 104 of forming a deep n-type well (DNW) in the first active region. The method 100 continues to operation 106 of forming a number of p-type wells (PW) and a number of n-type wells (NW) in the first active region and in the second active region, respectively. The method 100 continues to operation 108 of forming a number of nanostructures in the third active region. The method 100 continues to operation 110 of forming a dummy gate structure over the nanostructures. The method 100 continues to operation 112 of concurrently forming a number of epitaxial structures in the first to third active regions. The method 100 continues to operation 114 of doping the PW in the first active region and the NW in the second active region with respectively opposite conductive types. The method 100 continues to operation 116 of forming an active gate structure. The method 100 continues to operation 118 of forming a number of interconnect structures.

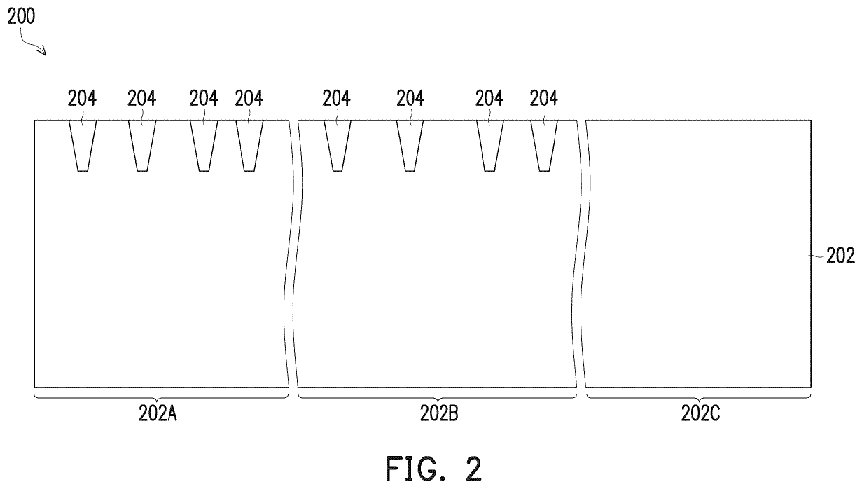

Corresponding to operation 102 of FIG. 1, FIG. 2 illustrates a cross-sectional view of the semiconductor device 200 including a substrate 202 with a first active region 202A, a second active region 202B, and a third active region 202C respectively defined at one of the various stages of fabrication, in accordance with various embodiments.

The substrate 202 may be a semiconductor substrate, such as a bulk semiconductor, a semiconductor-on-insulator (SOI) substrate, or the like, which may be doped (e.g., with a p-type or an n-type dopant) or undoped. The substrate 202 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 202 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In various embodiments, the first to third active regions, 202A-202C, may be defined on the substrate 202 to form a number of transistors, respectively. The active regions 202A to 202C may each be defined (e.g., partially or fully enclosed) by at least one respective isolation region, which is shown as a divider in FIG. 2 (and the following figures) for the purposes of clarity. Such an isolation region may be formed as a shallow trench isolation (STI) structure along a top surface of the substrate 202. The STI structure may be formed by recessing the substrate 202 with a certain depth, filling the recess(es) with an insulation material, and polishing the workpiece until the top surface of the substrate 202 is exposed. However, it should be appreciated that the isolation region can be formed as a field oxide, while remaining within the scope of the present disclosure. The insulation material may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used.

Further, within each of the active regions 202A-202B, the semiconductor device 200 can include one or more such STI structures (e.g., 204) configured to electrically isolate different features within the respective active region. For example, the first active region 202A can be defined to form a p-type JFET (pJFET); the second active region 202B can be defined to form an n-type JFET (nJFET); and the third active region 202C can be defined to form a GAA FET, in accordance with various embodiments. As will be discussed below, the STI structures 204, in the active region 202A, can electrically isolate a first gate region, a second gate region, and a channel region of the p-type JFET (pJFET) from one another; and the STI structures 204, in the active region 202B, can electrically isolate a first gate region, a second gate region, and a channel region of the n-type JFET (nJFET) from one another. Although no STI structure is visible in such a cross-sectional view of the active region 202C, it should be understood that one or more STI structures are visible in another cross-sectional view of the active region 202C.

Corresponding to operation 104 of FIG. 1, FIG. 3 illustrates a cross-sectional view of the semiconductor device 200 in which a deep n-type well (DNW) 302 is formed in the first active region 202A at one of the various stages of fabrication, in accordance with various embodiments.

The DNW 302 is formed in the first active region 202A of the substrate 202. In some embodiments, the formation of DNW 302 can include forming a photo resist, and implanting an n-type impurity such as phosphorous, arsenic, antimony, or the like into the first active region 202A. Such a photo resist is then removed. In some embodiments, a bottom surface of DNW 302 is lower than a bottom surface of the STI structures 204. For example, the DNW 302 may have a depth (e.g., measured from the top surface of the substrate 202 to the bottom surface of the DNW 302) greater than 200 nanometers (nm). An example impurity concentration in the DNW 302 is between about 1×10¹³ cm⁻³ and about 1×10¹⁵ cm⁻³ through an implant process with an energy level of about 200 kiloelectron volts (KeV) to about 500 KeV.

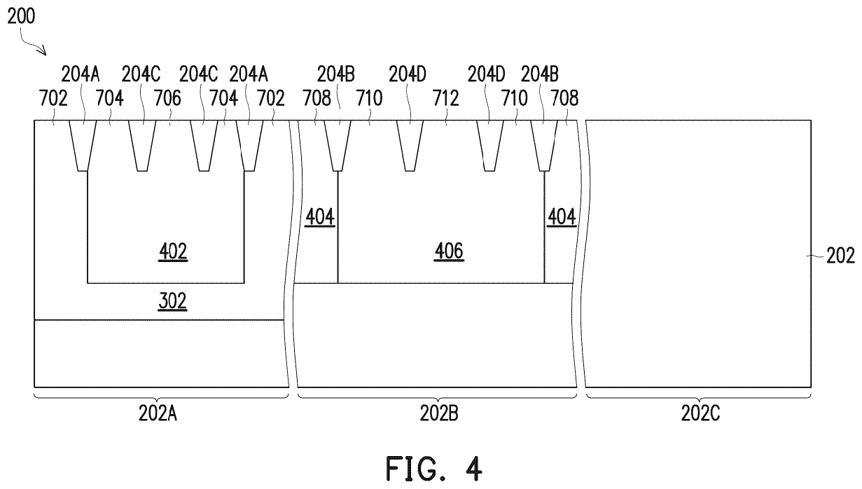

Corresponding to operation 106 of FIG. 1, FIG. 4 illustrates a cross-sectional view of the semiconductor device 200 in which a p-type well (PW) 402 is formed in the first active region 202A and a PW 404 and an n-type well (NW) 406 is formed in the second active region 202B at one of the various stages of fabrication, in accordance with various embodiments.

In the first active region 202A, the PW 402 is formed within the DNW 302, with two of the STI structures 204A each located at an interface between a vertical portion of the DNW 302 and the PW 402, as shown in FIG. 4. The formation of PW 402 can include forming and patterning a photo resist with a pattern exposing an area of the first active region 202A that is between the STI structures 204A, and implanting a p-type impurity such as boron, gallium, indium, aluminum, or the like into an intermediate level of the DNW 302. For example, the PW 402 may have a depth (e.g., measured from the top surface of the substrate 202 to a bottom surface of the PW 402) between about 50 nm and about 200 nm. The photo resist is then removed. An example impurity concentration in the PW 402 is between about 5×10¹³ cm⁻³ and about 5×10¹⁴ cm⁻³ through an implant process with an energy level of about 100 KeV to about 300 KeV.

In the second active region 202B, the PW 404 and NW 406 are formed within the substrate 202, with two of the STI structures 204B each located at an interface between the PW 404 and NW 406, as shown in FIG. 4. In some embodiments, the PW 404 may be first formed, followed by the formation of the NW 406. However, it should be understood that the formation order may be reversed, while remaining within the scope of the present disclosure. Further, the PW 404 in the second active region 202B may be concurrently formed with the PW 402 in the first active region 202A, in some embodiments.

The formation of PW 404 can include forming and patterning a first photo resist with a pattern exposing an area of the second active region 202B that is outside the STI structures 204B, and implanting a p-type impurity such as boron, gallium, indium, aluminum, or the like into the second active region 202B. For example, the PW 404 may have a depth (e.g., measured from the top surface of the substrate 202 to a bottom surface of the PW 404) between about 50 nm and about 200 nm. The first photo resist is then removed. Subsequently to or prior to the formation of the PW 404, the NW 406 is formed by forming and patterning a second photo resist with a pattern exposing an area of the second active region 202B that is inside the STI structures 204B, and implanting an n-type impurity such as phosphorous, arsenic, antimony, or the like into the second active region 202B. The NW 406 may have a depth substantially similar to the depth of the PW 404 (e.g., between about 50 nm and about 200 nm). The second photo resist is then removed. An example impurity concentration in the PW 404 and NW 406 is between about 5×10¹³ cm⁻³ and about 5×10¹⁴ cm⁻³ through respective implant processes with an energy level of about 100 KeV to about 300 KeV.

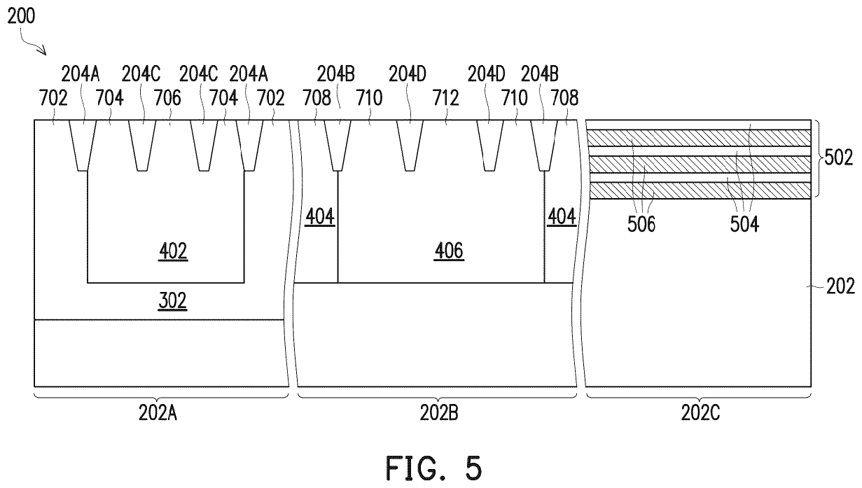

Corresponding to operation 108 of FIG. 1, FIG. 5 illustrates a cross-sectional view of the semiconductor device 200 in which a fin structure 502 is formed in the third active region 202C at one of the various stages of fabrication, in accordance with various embodiments.

As shown, the fin structure 502 may include a number of first nanostructures (first semiconductor layers) 504 and a number of second nanostructures (second semiconductor layers) 506 alternately arranged on top of one another. For example, one of the second semiconductor layers 506 is disposed over one of the first semiconductor layers 504 then another one of the first semiconductor layers 504 is disposed over the second semiconductor layer 506, so on and so forth. The fin structure 502 may include any number of alternately disposed first and second semiconductor layers.

The semiconductor layers 504 and 506 may have respective different thicknesses. Further, the first semiconductor layers 504 may have different thicknesses from one layer to another layer. The second semiconductor layers 506 may have different thicknesses from one layer to another layer. The thickness of each of the semiconductor layers 504 and 506 may range from few nanometers to few tens of nanometers. The first layer of the fin structure 502 may be thicker than other semiconductor layers 504 and 506. In an embodiment, each of the first semiconductor layers 504 has a thickness ranging from about 5 nm to about 20 nm, and each of the second semiconductor layers 506 has a thickness ranging from about 5 nm to about 20 nm.

The two semiconductor layers 504 and 506 have different compositions. In various embodiments, the two semiconductor layers 504 and 506 have compositions that provide for different oxidation rates and/or different etch selectivity between the layers. In an embodiment, the second semiconductor layers 506 include silicon germanium (Si₁₋ₓGeₓ), and the first semiconductor layers 504 include silicon (Si). In an embodiment, each of the semiconductor layers 504 is silicon that may be undoped or substantially dopant-free (i.e., having an extrinsic dopant concentration from about 0 cm⁻³ to about 1×10¹⁷ cm⁻³), where for example, no intentional doping is performed when forming the semiconductor layers 504 (e.g., of silicon). Either of the semiconductor layers 504 and 506 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. The materials of the semiconductor layers 504 and 506 may be chosen based on providing differing oxidation rates and/or etch selectivity.

The semiconductor layers 504 and 506 can be epitaxially grown from the semiconductor substrate 202. For example, each of the semiconductor layers 504 and 506 may be grown by a molecular beam epitaxy (MBE) process, a chemical vapor deposition (CVD) process such as a metal organic CVD (MOCVD) process, and/or other suitable epitaxial growth processes. During the epitaxial growth, the crystal structure of the semiconductor substrate 202 extends upwardly, resulting in the semiconductor layers 504 and 506 having the same crystal orientation with the semiconductor substrate 202.

Upon growing the semiconductor layers 504 and 506 on the semiconductor substrate 202 (as a stack), the stack may be patterned to form the fin structure 502 shown in FIG. 5. The fin structure can elongate along a lateral direction, and includes a stack of patterned semiconductor layers 504-506 interleaved with each other. The fin structure 502 is formed by patterning the stack of semiconductor layers 504-506 and the semiconductor substrate 202 using, for example, photolithography and etching techniques. Following the formation of the fin structure 502, an STI structure (not shown) may be formed in the third active region 202C to enclose a lower portion of the fin structure 502.

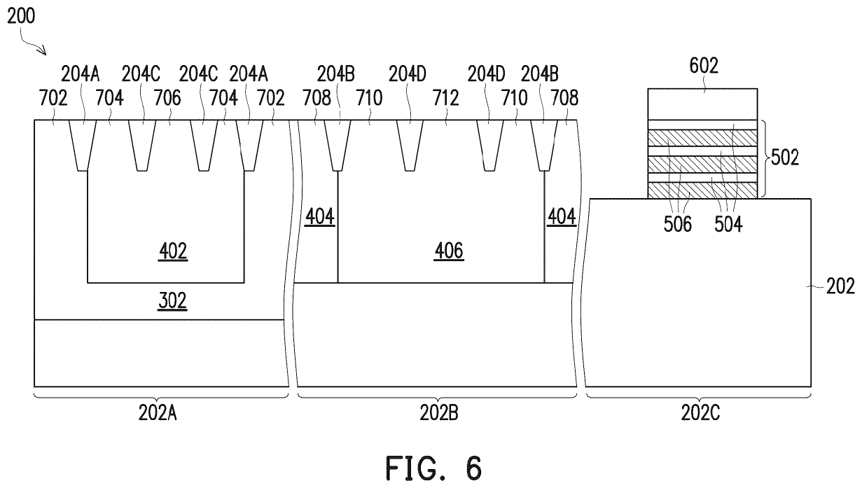

Corresponding to operation 110 of FIG. 1, FIG. 6 illustrates a cross-sectional view of the semiconductor device 200 in which a dummy gate structure 602 is formed over the fin structure 502 at one of the various stages of fabrication, in accordance with various embodiments.

The dummy gate structure 602 includes a dummy gate dielectric and a dummy gate (not separately shown), in some embodiments. To form the dummy gate structure 602, a dielectric layer is formed on the fin structure 502. The dielectric layer may be, for example, silicon oxide, silicon nitride, silicon oxynitride, silicon carbide, silicon carbonitride, silicon oxycarbonitride, silicon oxycarbide, multilayers thereof, or the like, and may be deposited or thermally grown. Next, a gate layer is formed over the dielectric layer, and a mask layer is formed over the gate layer. The gate layer may be deposited over the dielectric layer and then planarized, such as by a CMP. The mask layer may be deposited over the gate layer. The gate layer may be formed of, for example, polysilicon, although other materials may also be used. The mask layer may be formed of, for example, silicon nitride or the like.

After the layers (e.g., the dielectric layer, the gate layer, and the mask layer) are formed, the mask layer may be patterned using suitable lithography and etching techniques. The pattern of the mask layer then may be transferred to the gate layer and the dielectric layer by a suitable etching technique to form the dummy gate structure 602. The dummy gate structure 602 may have a lengthwise direction perpendicular to the lengthwise direction of the fin structure 502. As such, the dummy gate structure 602 can cover a portion (e.g., a channel region) of the fin structure 502. Alternatively stated, the dummy gate structure 602 can straddle or otherwise overlay a (e.g., central) portion the fin structure 502, with side portions of the fin structure 502 exposed. Next, such non-overlaid side portions of the fin structure 502 may be removed through an anisotropic etching process (e.g., a reactive ion etching (RIE) process, a neutral beam etching (NBE) process, or the like). Accordingly, ends (or sidewalls) of each of the semiconductor layers 504 and 506 may be vertically aligned with sidewalls of the dummy gate structure 602, respectively, as shown in FIG. 6.

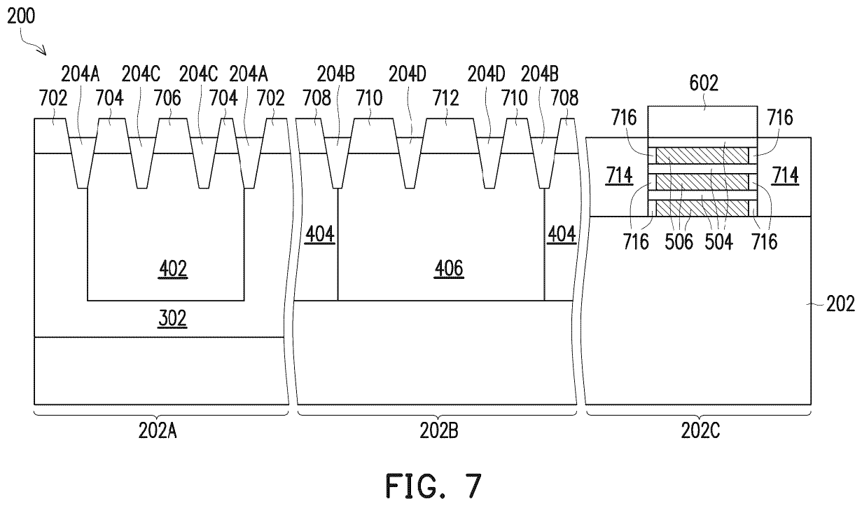

Corresponding to operation 112 of FIG. 1, FIG. 7 illustrates a cross-sectional view of the semiconductor device 200 in which a number of epitaxial structures, 702, 704, 706, 708, 710, 712, and 714, may be concurrently formed in the first to third active regions 202A-202C at one of the various stages of fabrication, in accordance with various embodiments.

As shown, in the first active region 202A, a pair of epitaxial structures 702 are formed at end exposed portions of the DNW 302 (e.g., along the top surface of the substrate 202), respectively; a pair of epitaxial structures 704 are formed at exposed end portions of the PW 402 (e.g., along the top surface of the substrate 202), respectively; and an epitaxial structure 706 is formed at an exposed portion of the PW 402. The epitaxial structures 702 may be electrically isolated from the epitaxial structures 704 with the STI structures 204A; and the epitaxial structures 704 may be electrically isolated from the epitaxial structure 706 with the STI structures 204C. In some embodiments, the epitaxial structures 702 may have an n-type conductivity; the epitaxial structures 704 may have a p-type conductivity; and the epitaxial structure 706 may have an n-type conductivity.

In the second active region 202B, a pair of epitaxial structures 708 are formed at end exposed portions of the PW 404 (e.g., along the top surface of the substrate 202), respectively; a pair of epitaxial structures 710 are formed at exposed end portions of the NW 406 (e.g., along the top surface of the substrate 202), respectively; and an epitaxial structure 712 is formed at an exposed portion of the NW 406. The epitaxial structures 708 may be electrically isolated from the epitaxial structures 710 with the STI structures 204B; and the epitaxial structures 710 may be electrically isolated from the epitaxial structure 712 with the STI structures 204D. In some embodiments, the epitaxial structures 708 may have a p-type conductivity; the epitaxial structures 710 may have an n-type conductivity; and the epitaxial structure 712 may have a p-type conductivity.

In the third active region 202C, a pair of epitaxial structures 714 are formed on the sides of the fin structure 502. Specifically, the epitaxial structures 714 are formed on (extended from) respective ends of each of the semiconductor layers 504. Depending on a conductive type of the completed GAA FET (formed in the third active region 202C), the epitaxial structures 714 can have a corresponding conductive type. For example, when the GAA FET is configured as a n-type transistor, the epitaxial structures 714 have an n-type conductivity; and when the GAA FET is configured as a p-type transistor, the epitaxial structures 714 have a p-type conductivity. Prior to forming the epitaxial structures 714, the semiconductor layers 506 are recessed with respect to the sidewalls of the dummy gate structure 602 based on a pull-back process. The pull-back process may include a hydrogen chloride (HCl) gas isotropic etching process, which etches SiGe (e.g., semiconductor layers 506) without attacking Si (e.g., semiconductor layers 504). Next, a number of inner spacers 716 are formed by filling the recesses with an insulation material (e.g., silicon nitride, silicon boron carbonitride, silicon carbonitride, silicon carbon oxynitride, or the like), respectively.

In various embodiments, the epitaxial structures 702 to 714 may be concurrently formed in one or more epitaxial growth processes. For example, the epitaxial structures 702, 706, 710, and 714 (if configured in n-type) can be formed in a first epitaxial growth processes; and the epitaxial structures 704, 708, 712, and 714 (if configured in p-type) can be formed in a second epitaxial growth processes. As such, respective source regions, drain regions, and gate regions of the pJEFT (formed in the active region 202A), respective source regions, drain regions, and gate regions of the nJFET (formed in the active region 202B), and a source region and drain region of the GAA FET (formed in the active region 202C) can be concurrently formed in a reduced number of epitaxial growth processes, which will be discussed in further detail below. In this way, the cost to integrate both MOS-based transistors (e.g., GAA FETs) and non-MOS-based transistors (e.g., JFETs) can be significantly reduced.

The epitaxial structures 702 to 714 may each include silicon germanium (SiGe), indium arsenide (InAs), indium gallium arsenide (InGaAs), indium antimonide (InSb), gallium arsenide (GaAs), gallium antimonide (GaSb), indium aluminum phosphide (InAlP), indium phosphide (InP), any other suitable material, or combinations thereof. The epitaxial structures 702 to 714 may be formed using an epitaxial layer growth process on exposed portions of a semiconductor body, for example, exposed potions of the DNW 302, exposed portions of the PW 402, exposed portions of the PW 404, exposed portions of the NW 406, and exposed ends of the semiconductor layers 504. In some embodiments, the growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. In-situ doping (ISD) may be applied to form the doped epitaxial structures 702 to 714. For example, the epitaxial structures 702, 706, 710, and 714 (if the GAA FET is configured in n-type) can be doped by implanting n-type dopants, e.g., arsenic (As), phosphorous (P), etc., into them. The epitaxial structures 704, 708, 712, and 714 (if the GAA FET is configured in p-type) can be doped by implanting p-type dopants, e.g., boron (B), etc., into them.

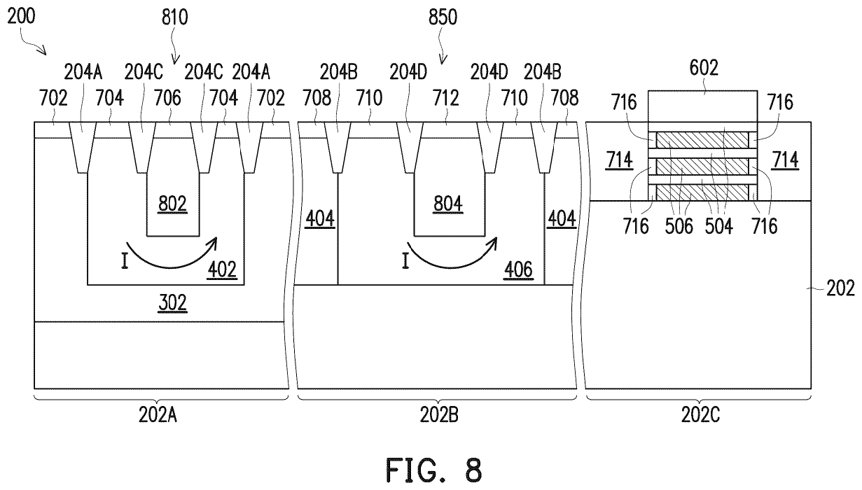

Corresponding to operation 114 of FIG. 1, FIG. 8 illustrates a cross-sectional view of the semiconductor device 200 in which a highly doped NW 802 is formed in the PW 402 and a highly doped PW 804 is formed in the NW 406 at one of the various stages of fabrication, in accordance with various embodiments.

In the first active region 202A, the highly doped NW 802 is formed within the PW 402, with two of the STI structures 204C each located at an interface between a vertical portion of the PW 402 and the NW 802, as shown in FIG. 8. The formation of NW 802 can include forming and patterning a photo resist with a pattern exposing an area of the first active region 202A that is between the STI structures 204C, and implanting an n-type impurity such as phosphorous, arsenic, antimony, or the like into the PW 402. For example, the NW 802 may have a depth (e.g., measured from the top surface of the substrate 202 to a bottom surface of the NW 802) between about 15 nm and about 50 nm. The photo resist is then removed. An example impurity concentration in the NW 802 is between about 5×10¹⁴ cm⁻³ and about 5×10¹⁵ cm⁻³ through an implant process with an energy level of about 25 KeV to about 100 KeV.

In the second active region 202B, the highly doped PW 804 is formed within the NW 406, with two of the STI structures 204D each located at an interface between the NW 406 and PW 804, as shown in FIG. 8. The formation of PW 804 can include forming and patterning a photo resist with a pattern exposing an area of the second active region 202B that is between the STI structures 204D, and implanting a p-type impurity such as boron, gallium, indium, aluminum, or the like into the NW 406. For example, the PW 804 may have a depth (e.g., measured from the top surface of the substrate 202 to a bottom surface of the PW 804) between about 15 nm and about 50 nm. The photo resist is then removed. An example impurity concentration in the PW 804 is between about 5×10¹⁴ cm⁻³ and about 5×10¹⁵ cm⁻³ through an implant process with an energy level of about 25 KeV to about 100 KeV.

After forming the NW 802 in the PW 402 and the PW 804 in the NW 406, a polishing process (e.g., a chemical mechanical polishing (CMP) process) may be performed in the active regions 202A and 202B to level the top surface of the STI structures 204 and the epitaxial structures 702 to 712. Following the polishing process, the above-mentioned pJFET (hereinafter referenced as “pJFET 810”) and the nJFET (hereinafter referenced as “nJFET 850”) can be formed in the active regions 202A and 202B, respectively, in accordance with some embodiments. Using such a structure not based on MOS, these JFETs are suitable for some noise-sensitive applications. For example, by connecting one pJFET to one nJFET in series, an inverter can be formed. Constructing an inverter based on the disclosed JFET structures, the inverter can be used in at least one of a number of delay cells connected to each other.

In various embodiments, each of the pJFET 810 and nJFET 850 may have a first gate region (structure) and a second gate region (structure) sandwiching a channel region therebetween. The first gate region may be formed in a first U-shape enclosing the second gate region that is formed in a well shape. Further, the channel region may be formed in a second U-shape interposed between the first gate region and the channel region. For example, the DNW 302 (which is formed in an U-shape) can function as a first (bottom) gate region of the pJFET 810, with the epitaxial structures 702 operatively serving as a first gate contact; the PW 402 (which is also formed in an U-shape) can function as a channel region of the pJFET 810, with the epitaxial structures 704 operatively serving as a drain contact and a source contact, respectively; and the highly doped NW 802 (which is formed in a well shape) can function as a second (top) gate region of the pJFET 810, with the epitaxial structure 706 operatively serving as a second gate contact. The PW 404 (which is formed in a well shape) can function as a first (bottom) gate region of the nJFET 850, with the epitaxial structures 708 operatively serving as a first gate contact; the NW 406 (which is formed in an U-shape) can function as a channel region of the nJFET 850, with the epitaxial structures 710 operatively serving as a drain contact and a source contact, respectively; and the highly doped PW 804 (which is formed in a well shape) can function as a second (top) gate region of the nJFET 850, with the epitaxial structure 712 operatively serving as a second gate contact.

In operation, the channel region 402/406 can be controlled by the first gate region 302/404 and the second gate region 802/804. By adjusting a (e.g., reverse) gate voltage applied on each of the first gate contact 702/708 and second gate contact 706/712, the width of a channel in the channel region 402/406 can be modulated, thereby controlling the level of current flowing through the channel region 402/406. For example, the channel region can be turned on or pinched off by a first depletion region formed between the first gate region and the channel region, and a second depletion region formed between the second gate region and the channel region. Current “I” may flow from the drain contact 704/710, through the channel in the channel region 402/406, and to the source contact 704/710, as illustrated. As a non-limiting example, in the operation of the pJFET 810, a negative gate voltage (e.g., in the range of about −1 V to about 0 V) may be applied to the first and second gate contacts 702 and 706 and a positive voltage may be applied to one of the (drain) contacts 704, with the other (source) contact 704 connected to ground; and in the operation of the nJFET 850, a positive gate voltage (e.g., in the range of about 0 V to about 1 V) may be applied to the first and second gate contacts 708 and 712 and a negative voltage may be applied to one of the (drain) contacts 710, with the other (source) contact 710 connected to ground. Although not shown, voltage sources may be connected to the first gate contact 702/708 and the second gate contact 706/712 in order to provide the respective gate voltages, which may be identical to or different from each other.

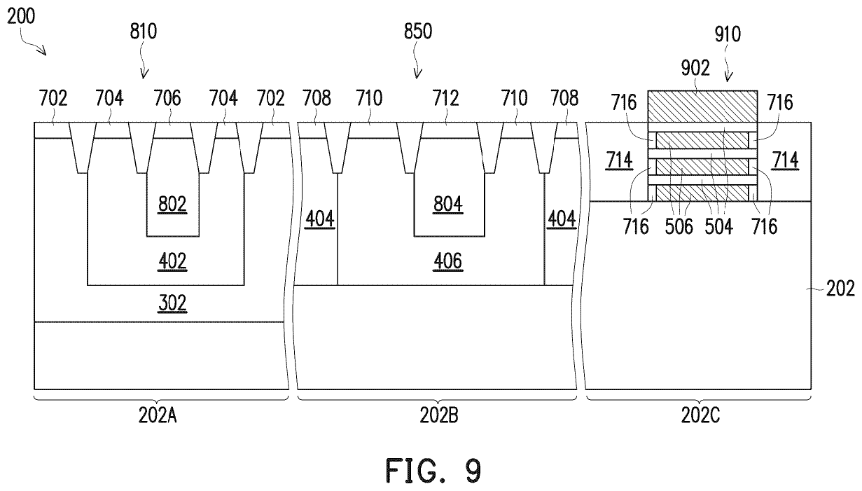

Corresponding to operation 116 of FIG. 1, FIG. 9 illustrates a cross-sectional view of the semiconductor device 200 in which an active (e.g., metal) gate structure 902 is formed in the third active region 202C at one of the various stages of fabrication, in accordance with various embodiments.

The active gate structure 902 can be formed by replacing the dummy gate structure 602 and the semiconductor layers 506 first with a gate dielectric and then a gate metal (which are separately shown), in some embodiments. For example, the dummy gate structure 602 and the semiconductor (SiGe) layers 506 may be concurrently or individually removed. After the removal, respective top and bottom surfaces of the semiconductor (Si) layers 504 may be exposed, with their ends (sidewalls) still connected to the epitaxial structures 714. Next, the gate dielectric is first deposited, followed with deposition of the gate metal. As such, the gate dielectric can wrap around each of the semiconductor layers 504, and the gate metal can wrap around each of the semiconductor layers 504, with the gate dielectric disposed therebetween.

The gate dielectric includes silicon oxide, silicon nitride, or multilayers thereof. In example embodiments, the gate dielectric includes a high-k dielectric material, and in these embodiments, the gate dielectric may have a k value greater than about 7.0, and may include a metal oxide or a silicate of Hf, Al, Zr, La, Mg, Ba, Ti, Pb, or combinations thereof. The formation methods of gate dielectric may include molecular beam deposition (MBD), atomic layer deposition (ALD), PECVD, and the like. A thickness of the gate dielectric may be between about 8 angstroms (Å) and about 20 Å, as an example.

The metal gate is formed over the corresponding gate dielectric. The metal gate may be a P-type work function layer, an N-type work function layer, multi-layers thereof, or combinations thereof, in some embodiments. Accordingly, the metal gate is sometimes referred to as a work function layer. In the discussion herein, a work function layer may also be referred to as a work function metal. Example P-type work function metals that may be included in the gate structures for P-type devices include TiN, TaN, Ru, Mo, Al, WN, ZrSi2, MoSi2, TaSi2, NiSi2, WN, other suitable P-type work function materials, or combinations thereof. Example N-type work function metals that may be included in the gate structures for N-type devices include Ti, Ag, TaAl, TaAlC, TiAlN, TaC, TaCN, TaSiN, Mn, Zr, other suitable N-type work function materials, or combinations thereof.

Upon forming the active gate structure 902, the above-mentioned GAA FET (referenced as “GAA FET 910”) can be formed. The semiconductor layers 504 may collective function as a channel of the GAA FET 910. The semiconductor layers 504 of such a channel are each wrapped by the active gate structure 902. The epitaxial structures 714 can function as a source structure and a drain structure of the GAA FET 902, respectively.

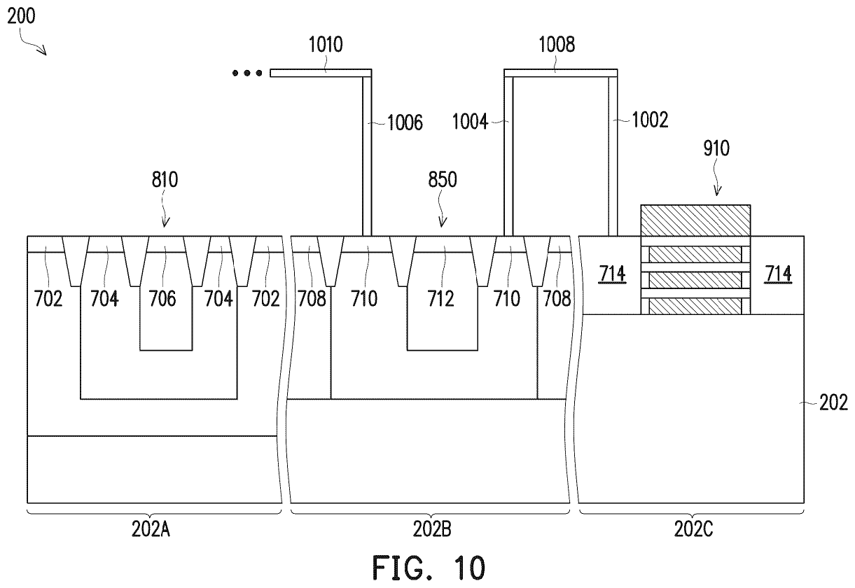

Corresponding to operation 118 of FIG. 1, FIG. 10 illustrates a cross-sectional view of the semiconductor device 200 in which a number of interconnect structures 1002, 1004, 1006, 1008, and 1010 are formed at one of the various stages of fabrication, in accordance with various embodiments.

After forming the pJFET 810, nFET 850, and GAA FET 910 in the active regions 202A, 202B, and 202C, respectively, a number of interconnect structures (formed of one or more metal materials, e.g., copper, aluminum, etc.) can be formed to electrically connect at least two of the pJFET 810, nFET 850, or GAA FET 910 to one another, forming an integrated circuit that has a certain function. For example, the interconnect structure 1002 (formed as a via) is in electrical contact with one of the epitaxial structures 714 (e.g., a source structure) of the GAA FET 910; the interconnect structure 1004 (formed as a via) is in electrical contact with one of the epitaxial structures 710 (e.g., a drain structure) of the nJFET 850; the interconnect structure 1006 (formed as a via) is in electrical contact with the other of the epitaxial structures 710 (e.g., a source structure) of the nJFET 850; the interconnect structure 1008 (formed as a metal line) electrically connects the via 1002 to the via 1004 (thereby coupling the source structure of the GAA FET 910 to the drain structure of the nJFET 850); and the interconnect structure 1010 (formed as a metal line) electrically connects the via 1006 to another via not being shown (thereby coupling the source structure of the nJFET 850 to another device structure).

In some embodiments, the example interconnect structures 1002, 1004, 1006, 1008, and 1010 can be formed across one or more of a number of metallization layers above the transistor structures (e.g., pJFET 810, nJFET 850, GAA FET 910). Such metallization layers may each have a number of metal lines and/or vias (e.g., 1002 to 1010) formed within an intermetal dielectric (IMD) material. The IMD material includes, but is not limited to, silicon oxide, phosphosilicate glass (PSG), borosilicate glass (BSG), boron-doped phosphosilicate Glass (BPSG), undoped silicate glass (USG), or the like. The IMD material may be deposited by any suitable method, such as CVD, PECVD, or FCVD. The corresponding metal lines and/or vias formed therein may be formed by one or more single and/or duo damascene processes. These metallization layers are sometimes collectively referred to as back-end-of-line (BEOL) processing/networking, while the transistor structures are sometimes collectively referred to as front-end-of-line (FEOL) processing/networking.

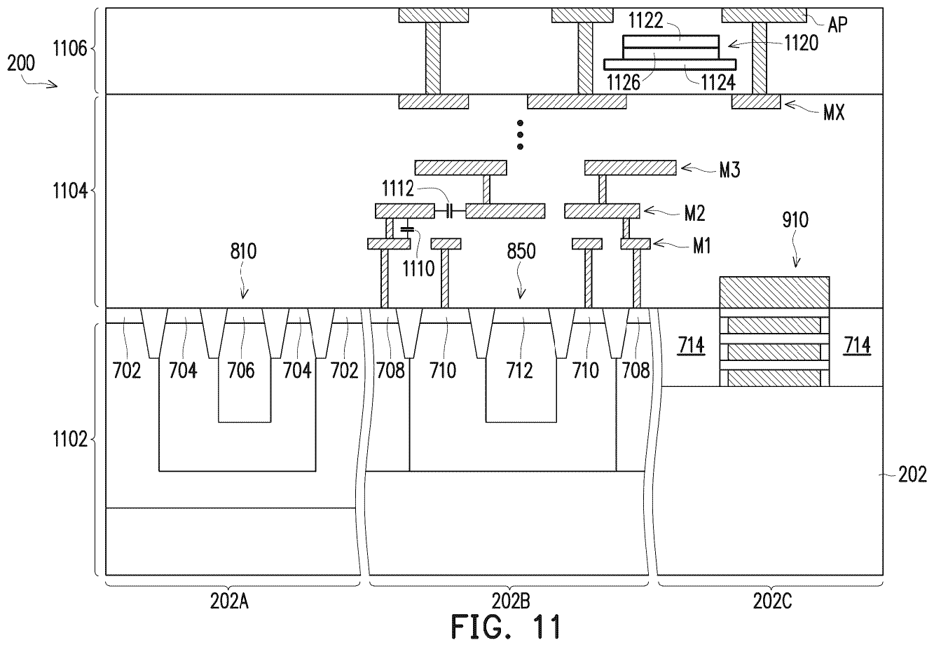

FIG. 11 illustrates a cross-sectional view of the semiconductor device 200 in which a number of other devices, e.g., 1110, 1112, 1120, etc., are formed in the BEOL networking at one of the various stages of fabrication, in accordance with various embodiments. As shown, the pJFET 810, nJFET 850, and GAA FET 910 are formed in a FEOL networking (e.g., 1102), with a number of interconnect structures formed in a BEOL networking (e.g., 1104 and 1106). In some embodiments, in a first portion of the BEOL networking 1104, metallization layers, M1, M2, M3 . . . Mx, each of which includes a number of corresponding metal lines and a number of corresponding vias connecting the metal lines in adjacent metallization layers, are formed. Beyond the first portion 1104, a second portion of the BEOL networking 1106 including one or more conductor (e.g., aluminum) pads, AP, configured to connect the semiconductor device 200 to one or more other semiconductor devices are formed.

Further, within the first portion 1104, one or more metal-oxide-metal (MOM) capacitors, e.g., 1110 and 1112, can be formed; and within the second portion 1106, one or more metal-insulator-metal (MIM) capacitors, 1120, can be formed. The MOM capacitor 1110 can include the metal lines of different metallization (e.g., M1 and M2) layers functioning as respective electrodes; the MOM capacitor 1112 can include the metal lines within the same metallization (e.g., M2) layer functioning as respective electrodes; and the MIM capacitor 1120 can include a first metal film 1122 functioning as a first electrode, a second metal film 1124 functioning as a second electrode, and a dielectric layer 1126 functioning as a dielectric medium between the first and second electrodes. In some embodiments, the MIM capacitor 1120 is formed between the topmost metallization layer Mx and the conductor pad AP. In some embodiments, the FEOL structures can be in electrical contact with one or more of the BEOL devices.

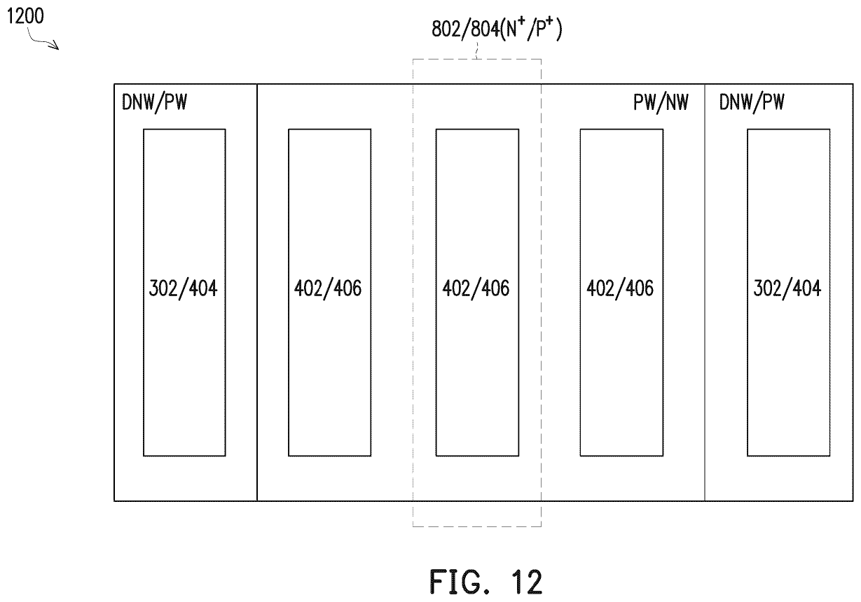

FIG. 12 illustrates an example layout 1200 to form at least one of the pJFET 810 or nJFET 850, in accordance with various embodiments. It should be appreciated that there are more varieties as how the pJFET 810 and/or nJFET 850 may be laid out, and these varieties are also in the scope of the present disclosure.

As shown, the layout 1200 includes a DNW/PW to form the DNW 302/PW 404. Adjacent to or enclosed by the DNW/PW, the layout 1200 includes a PW/NW in which the PW 402/NW 406 is formed. The DNW 302/PW 404 may be defined as discrete oxide diffusion (OD) regions, as shown in FIG. 12, or a continuous OD region (e.g., a close-loop ring). Similarly, the PW 402/NW 406 may be defined as discrete OD regions, as shown in FIG. 12, or one or more continuous OD regions (e.g., one or more close-loop rings). Those discrete OD regions can be separated from one another by a number of STI structures. Further, the layout 1200 includes a pattern to define the highly doped NW 802 or the highly doped PW 804 that may be located over a middle one of the discrete OD regions 402/406, in some embodiments.

In one aspect of the present disclosure, a semiconductor device is disclosed. The semiconductor device includes a substrate. The semiconductor device includes a first gate region extending into the substrate and having at least a portion of a first U-shape. The semiconductor device includes a channel region extending into the substrate and having a second U-shape. The semiconductor device includes a second gate region extending into the substrate and having a well shape. The well shape is disposed between the second U-shape, and the second U-shape is disposed further between the first U-shape.

In another aspect of the present disclosure, a semiconductor device is disclosed. The semiconductor device includes a first junction field-effect-transistor comprising a first gate region extending into a substrate and having a first conductive type; a first channel region extending into the substrate and having a second conductive type opposite to the first conductive type, wherein the first channel region has a lower boundary surrounded by the first gate region; and a second gate region extending into the substrate and having the first conductive type, wherein the second gate region has a lower boundary surrounded by the first channel region.

In yet another aspect of the present disclosure, a method for fabricating semiconductor devices is disclosed. The method includes forming a first gate region extending into a substrate and having at least a vertical portion of a first U-shape, wherein the first gate region has a first conductive type. The method includes forming a channel region extending into the substrate and having a second U-shape surrounded by the first U-shape. The channel region has a second conductive type. The method includes forming a pair of first epitaxial structures coupled to end portions of the first gate region, respectively. The first epitaxial structures have the first conductive type. The method includes forming a pair of second epitaxial structures coupled to end portions of the channel region, respectively. The second epitaxial structures have the second conductive type. The method includes forming a third epitaxial structure having the first conductive type and surrounded by the second U-shape. The method includes forming a second gate region extending into the substrate and disposed below the third epitaxial structure. The second gate region has the first conductive type.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating semiconductor devices, comprising:
(a) forming a first gate region extending into a substrate and having at least a vertical portion of a first U-shape, wherein the first gate region has a first conductive type;
(b) forming a channel region extending into the substrate and having a second U-shape surrounded by the first U-shape, wherein the channel region has a second conductive type;
(c) forming a pair of first epitaxial structures coupled to end portions of the first gate region, respectively, wherein the first epitaxial structures have the first conductive type;
(d) forming a pair of second epitaxial structures coupled to end portions of the channel region, respectively, wherein the second epitaxial structures have the second conductive type;
(e) forming a third epitaxial structure having the first conductive type and surrounded by the second U-shape; and
(f) forming a second gate region extending into the substrate and disposed below the third epitaxial structure, wherein the second gate region has the first conductive type.

2. The method of claim 1, wherein the first gate region has a first doping concentration and the second gate region has a second doping concentration, the second doping concentration being higher by at least 10% than the first doping concentration.

3. The method of claim 1, wherein the channel region is completely enclosed by the first gate region and the second gate region such that the channel region is buried within the substrate and separated from direct contact with an isolation region to reduce flicker noise.

4. The method of claim 1, wherein the first gate region and second gate region are configured to collectively cause a depletion region along the channel region.

5. The method of claim 1, wherein the channel region comprises a pair of first portions disposed on sides of the second gate region, and a second portion disposed below the second gate region.

6. The method of claim 1, wherein the substrate further comprises a plurality of isolation regions, and wherein the second gate region is electrically isolated from the channel region with a first pair of the plurality of isolation regions, and the channel region is electrically isolated from the first gate region with a second pair of the plurality of isolation regions.

7. The method of claim 1, further comprising:
(g) forming a plurality of nanostructures vertically spaced apart from one another;
(h) forming a pair of fourth epitaxial structures coupled to ends of each of the plurality of nanostructures, respectively; and
(i) forming a gate structure wrapping around each of the plurality of nanostructures;
wherein the steps (c), (d), (e), and (h) are concurrently performed.

8. The method of claim 7, wherein one or more interconnect structures electrically couple the one of the second epitaxial structures to one of the fourth epitaxial structures.

9. A method for fabricating semiconductor devices, comprising:
forming a first junction field-effect-transistor comprising:
(a) forming a first gate region extending into a substrate, wherein the first gate region has a first conductive type,
(b) forming a channel region extending into the substrate and has a lower boundary surrounded by the first gate region, wherein the channel region has a second conductive type, and
(c) forming a second gate region extending into the substrate and having a lower boundary surrounded by the channel region, wherein the second gate region has the first conductive type,
wherein the channel region is completely enclosed by the first gate region and the second gate region such that the channel region is buried within the substrate and separated from isolation regions to reduce flicker noise.

10. The method of claim 9, wherein the first gate region has a first doping concentration and the second gate region has a second doping concentration, the second doping concentration being higher by at least 10% than the first doping concentration.

11. The method of claim 9, wherein the first gate region and the channel region each have a U-shaped cross-section, such that the first gate region has at least a vertical portion of a first U-shape and the channel region has a second U-shape surrounded by the first U-shape.

12. The method of claim 9, forming the first junction field-effect-transistor further comprises:
(d) forming a pair of first epitaxial structures coupled to end portions of the first gate region, respectively;
(e) forming a pair of second epitaxial structures coupled to end portions of the channel region, respectively;
(f) forming a third epitaxial structure coupled to an end portion of the second gate region,
wherein steps (d), (e), (f) are concurrently performed.

13. The method of claim 12, wherein the first epitaxial structures have the first conductive type, the second epitaxial structures have the second conductive type, and the second gate region has the first conductive type.

14. The method of claim 13, further comprising:
(g) forming a plurality of nanostructures vertically spaced apart from one another;
(h) forming a pair of fourth epitaxial structures coupled to ends of each of the plurality of nanostructures, respectively; and
(i) forming a gate structure wrapping around each of the plurality of nanostructures wherein the plurality of nanostructures are configured to be separated from isolation regions to reduce flicker noise;
wherein the steps (d), (e), (f), and (h) are concurrently performed.

15. The method of claim 9, wherein the first gate region and the second gate region are configured to collectively cause a depletion region along the channel region.

16. The method of claim 9, wherein the substrate further comprises a plurality of isolation regions, and wherein the second gate region is electrically isolated from the channel region with a first pair of the plurality of isolation regions, and the channel region is electrically isolated from the first gate region with a second pair of the plurality of isolation regions.

17. A method for fabricating semiconductor devices, comprising:
forming a first junction field-effect-transistor comprising:
(a) forming a first gate region extending into a substrate and having at least a vertical portion of a first U-shape, wherein the first gate region has a first conductive type;
(b) forming a first channel region extending into the substrate and has a lower boundary surrounded by the first gate region, wherein the first channel region has a second conductive type opposite to the first conductive type; and
(c) forming a second gate region extending into the substrate and having a lower boundary surrounded by the first channel region, wherein the second gate region has the first conductive type; and
forming a second junction field-effect-transistor comprising:
(d) forming a third gate region extending into the substrate, wherein the third gate region has the first conductive type;
(e) forming a second channel region extending into the substrate and having a lower boundary surrounded by the third gate region, wherein the second gate region has the second conductive type; and
(f) forming a fourth gate region extending into the substrate and having a lower boundary surrounded by the second channel region, wherein the fourth gate region has the first conductive type.

18. The method of claim 17, wherein the first gate region has a first doping concentration and the second gate region has a second doping concentration, the second doping concentration being higher by at least 10% than the first doping concentration.

19. The method of claim 17, wherein the first channel region is completely enclosed by the first gate region and the second gate region such that the first channel region is buried within the substrate and separated from direct contact with an isolation region to reduce flicker noise.

20. The method of claim 17, wherein the first gate region and second gate region are configured to collectively cause a depletion region along the first channel region.
